(19) United States
(12) Patent Application Publication
(10) Pub. No.: US 2023/0106883 A1
(43) Pub. Date: Apr. 6, 2023

(54) ENERGY-EFFICIENT FLUID DISTRIBUTOR FOR SERVER RACKS

(71) Applicant: Baidu USA LLC, Sunnyvale, CA (US)

(72) Inventor: Tianyi GAO, San Jose, CA (US)

(21) Appl. No.: 17/484,090

(22) Filed: Sep. 24, 2021

(51) Int. Cl. H05K 7/20; F25B 21/02

(52) U.S. Cl. CPC H05K 7/20272; F25B 21/02; H05K 7/20263; H05K 7/20772; H05K 7/20836; F25B 2321/023; F25B 2321/0252

(57) ABSTRACT

Embodiments are disclosed of a fluid distributor and systems with the fluid distributor. The fluid distributor includes a fluid supply conduit having a main supply inlet and a main supply outlet and a fluid return conduit having a main return inlet and a main return outlet. A thermoelectric assembly is sandwiched between the supply conduit and the return conduit. The thermoelectric assembly including a thermoelectric device sandwiched between a pair of thermally conductive layers, with one thermally conductive layer in thermal contact with the supply conduit and the other thermally conductive layer in thermal contact with the return conduit.

### TECHNICAL FIELD

The disclosed embodiments relate generally to information technology (IT) liquid cooling systems, but not exclusively, to an energy-efficient fluid distributor for use in and with IT racks.

### BACKGROUND

Modem data centers like cloud computing centers house enormous amounts of information technology (IT) equipment such as servers, blade servers, routers, edge servers, power supply units (PSUs), battery backup units (BBUs), etc. These individual pieces of IT equipment are typically housed in racks within the computing center, with multiple pieces of IT equipment in each rack. The racks are typically grouped into clusters within the data center.

As IT equipment has become more computationally powerful it also consumes more electricity and, as a result, generates more heat. This heat must be removed from the IT equipment to keep it operating properly. To keep up with this increasing need for heat removal, IT equipment has incorporated internal liquid cooling systems and, at the same time, the IT racks in which IT equipment is housed have incorporated rack-level liquid cooling systems that interface with the internal liquid cooling systems of the IT equipment.

Existing liquid-cooling systems use pumps to deliver cooling fluid to the cooling system and manifolds to distribute the cooling fluid to heat-generating components, but in existing solutions each component is separate from the other and performs only a single function: the pump pumps fluid, the manifolds distribute the fluid, and that is all they do. Existing solutions for designing rack or tank liquid cooling loop on only pure fluid loops or hardware piping with components.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a side view of an embodiment of a liquid-cooled information technology (IT) rack populated with various pieces of IT equipment.

FIGS. 2A-2B are views of an embodiment of a fluid distributor. FIG. 2A is a longitudinal view, FIG. 2B is a cross-sectional view taken substantially along section B-B in FIG. 2A or an axial view.

FIGS. 3A-3B are schematic drawings of embodiments of rack fluid distribution systems using the fluid distributor of FIGS. 2A-2B as rack manifolds.

FIG. 4 is a schematic drawing of an embodiment of a data center fluid distribution system using the fluid distributor of FIGS. 2A-2B as a data center fluid distribution loop and rack manifolds.

FIG. 5 is a side view of an embodiment of an immersion cooling system using the fluid distributor embodiment of FIGS. 2A-2B.

FIG. 6 is a flowchart illustrating an embodiment of the operation of the rack fluid distribution shown in FIGS. 3A-3B.

FIG. 7 is a flowchart illustrating an embodiment of the self-regulating operation of the rack fluid distribution shown in FIGS. 3A-3B.

FIG. 8 is a flowchart illustrating another embodiment of the self-regulating operation of the rack fluid distribution shown in FIGS. 3A-3B.

### DETAILED DESCRIPTION

Embodiments are described of a fluid distributor for use with information technology (IT) equipment such as a data center or an IT rack. Specific details are described to provide an understanding of the embodiments, but one skilled in the relevant art will recognize that the invention can be practiced without one or more of the described details or with other methods, components, materials, etc. In some instances, well-known structures, materials, or operations are not shown or described in detail but are nonetheless encompassed within the scope of the invention.

Reference throughout this specification to “one embodiment” or “an embodiment” means that a described feature, structure, or characteristic can be included in at least one described embodiment, so that appearances of “in one embodiment” or “in an embodiment” do not necessarily all refer to the same embodiment. Furthermore, the particular features, structures, or characteristics may be combined in any suitable manner in one or more embodiments. As used in this application, directional terms such as “front,” “rear,” “top,” “bottom,” “side,” “lateral,” “longitudinal,” etc., refer to the orientations of embodiments as they are presented in the drawings, but any directional term should not be interpreted to imply or require a particular orientation of the described embodiments when in actual use.

Embodiments are described below of a fluid distributor or recirculation loop design for server racks. The embodiments are used in data center and server cooling systems to improve energy efficiency, enable energy harvesting, and decrease carbon dioxide emission. In addition, the disclosed embodiments enable some or all of the following features:
High efficiency design and ease of implementation.
Significantly increase cooling system operation efficiency.
Improve IDC cooling efficiency and decrease carbon dioxide emission.
Compatible with existing rack and IDC systems, both cooling and power.
Compatible with different energy consumption units and energy storage units.
Self-regulating hardware design.
Compatible with different cooling systems.
Compatible with most of the data center architectures.

The described embodiments can enable efficient thermal energy harvesting for designing thermal loops using the native characteristics of the thermal systems and, at the same time, enable self-regulated features for system operations.

The embodiments include a distributor that packages two fluid conduits or loops together with an intermediate assembly that includes two conducting layers and a thermoelectric device. The thermoelectric device functions as an electric generator when the cool supply fluid and hot return fluid are circulated within the loop. The power generated by the thermoelectric device can be used to control a valve dedicated to the loop. The valve open ratio is controlled and operated by the power delivered to it. In an embodiment, the cooling fluid temperature is measured by a sensor on the supply loop, and it is used for controlling a switch on the electric circuit. Closing the switch enables power storage in an energy storage unit. The embodiments can be applied to both internal rack manifolds and external data center loops for both liquid cooling and single phase immersion cooling systems.

According one aspect, a fluid distributor includes a fluid supply conduit having a main supply inlet and a main supply outlet, a fluid return conduit having a main return inlet and a main return outlet, and a thermoelectric assembly sandwiched between the fluid supply conduit and the fluid return conduit, the thermoelectric assembly including a thermoelectric device sandwiched between a pair of thermally conductive layers, wherein one thermally conductive layer is in thermal contact with the fluid supply conduit and the other thermally conductive layer is in thermal contact with the fluid return conduit.

In one embodiment, the fluid distributor further includes quick-disconnect fittings attached to the main supply inlet, the main supply outlet, the main return inlet, and the main return outlet. The fluid supply conduit includes one or more auxiliary fluid outlets and the fluid return conduit includes one or more auxiliary fluid inlets. The fluid distributor further includes one or more electrical connections coupled to the thermoelectric device. The thermoelectric device is a composite device including multiple individual thermoelectric devices electrically coupled. The fluid distributor is a rack manifold with the main supply inlet adapted to be coupled to a facility fluid supply and the main return outlet adapted to be fluidly coupled to a facility fluid return. The fluid distributor further includes an immersion cooling tank fluidly coupled to the main supply outlet and the main return inlet are fluidly coupled to an immersion cooling tank.

According to another aspect, a rack assembly includes a rack adapted to house one or more pieces of IT equipment, wherein at least one of the one or more pieces of IT equipment includes a liquid-cooling system and a rack manifold positioned within the rack. The rack manifold includes a rack supply conduit having a main supply inlet and one or more auxiliary supply outlets, a rack return conduit having a main return outlet, and one or more auxiliary return inlets, and a valve that is fluidly coupled to the main return outlet, and a thermoelectric assembly sandwiched between the rack supply conduit and the rack return conduit, the thermoelectric assembly including a thermoelectric device sandwiched between a pair of thermally conductive layers. A thermally conductive layer is in thermal contact with the rack supply conduit and the other thermally conductive layer is in thermal contact with the rack return conduit. The at least one piece of IT equipment that includes a liquid-cooling system is adapted to be fluidly coupled to an auxiliary supply outlet and an auxiliary supply inlet.

In one embodiment, the valve is electrically coupled to the thermoelectric device, is activated by applying an electrical current, and has an opening ratio that varies with the applied electrical current. The rack assembly further includes a temperature sensor that measures a temperature at or upstream of the main supply inlet. The rack assembly further includes a switch coupled in an electrical connection between the thermoelectric device and the valve, wherein the switch can be opened and closed based on an output of the temperature sensor. The rack assembly further includes an energy storage unit positioned in the rack, the energy storage unit being electrically coupled to the thermoelectric device and being electrically coupled to the valve.

According to a further aspect, a cooling system includes a facility fluid distribution system including one or more distributor modules as described above, and one or more racks fluidly coupled to the facility fluid distribution system, wherein each rack is adapted to house one or more pieces of IT equipment, where at least one of the one or more pieces of IT equipment includes a liquid-cooling system.

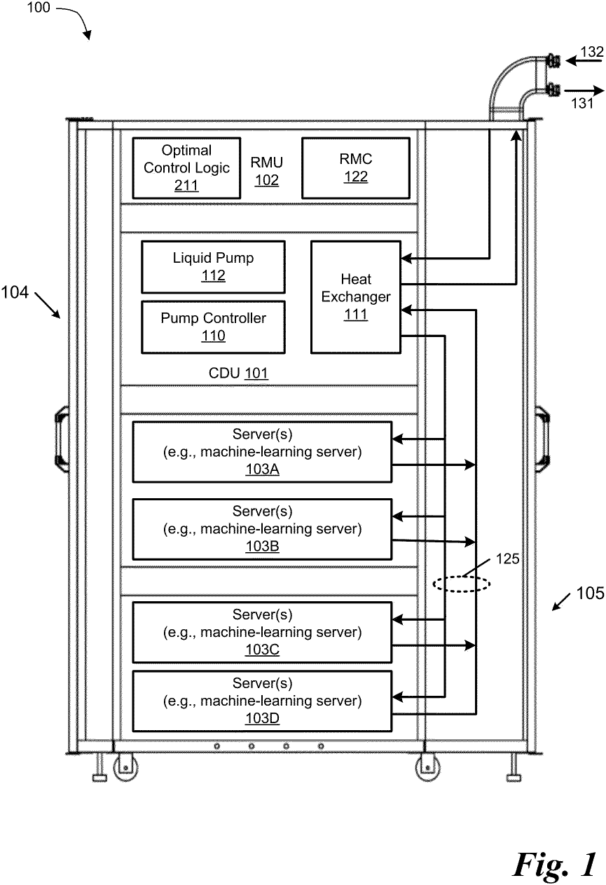

FIG. 1 is a block diagram illustrating a side view of an embodiment of an information technology (IT) rack, which is a type of IT container commonly used in data centers. In one embodiment, electronic rack 100 includes CDU 101, rack management unit (RMU) 102, and one or more server blades 103A-103D, collectively referred to as server blades 103. Server blades 103 can be inserted into an array of server slots respectively from front end 104 of electronic rack 100. Note that although only four server blades 103A-103D are shown, more or fewer server blades can be maintained within electronic rack 100. Also note that the particular positions of CDU 101, CMU 102, and server blades 103 are shown for the purpose of illustration only; other arrangements or configurations of CDU 101, CMU 102, and server blades 103 can also be implemented. Further, the front door disposed on front end 104 and the back door disposed on back end 105 are optional. In some embodiments, there can no door on front end 104 and/or back end 105.

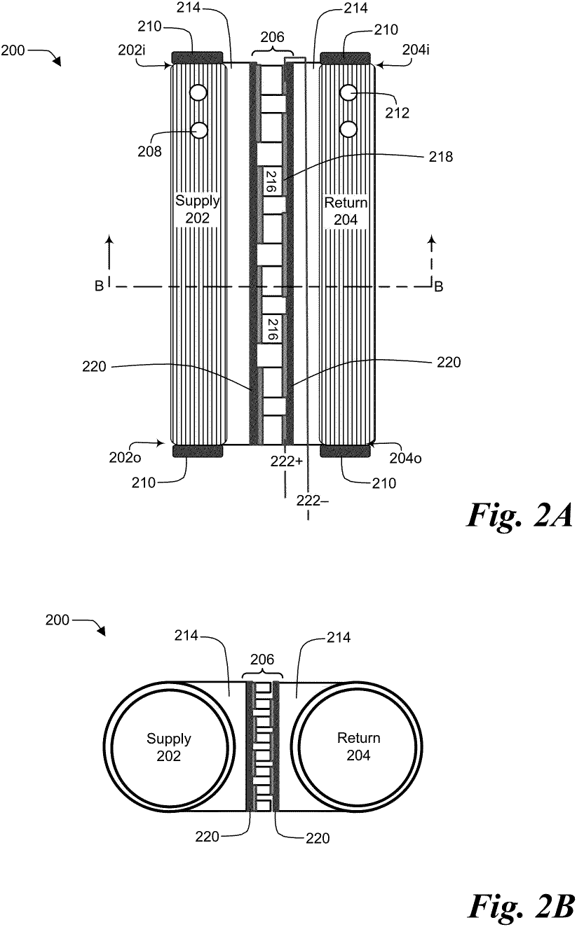

In one embodiment, CDU 101 includes heat exchanger 111, liquid pump 112, and pump controller 110. Heat exchanger 111 can be a liquid-to-liquid heat exchanger. Heat exchanger 111 includes a first tube having a first pair of liquid connectors coupled to external liquid supply/return lines 131-132 to form a primary loop, where the connectors coupled to the external liquid supply/return lines 131-132 can be disposed or mounted on back end 105 of electronic rack 100. In addition, heat exchanger 111 further includes a second tube having a second pair of liquid connectors coupled to liquid manifold 125, which can include a supply manifold to supply cooling liquid to server blades 103 and a return manifold to return warmer liquid back to CDU 101. The processors can be mounted on the cold plates, where the cold plates include a liquid distribution channel embedded therein to receive the cooling liquid from the liquid manifold 125 and to return the cooling liquid carrying the heat exchanged from the processors back to the liquid manifold 125. Rack 100 is an example of an IT rack in which embodiments of a fluid distributor, such as the ones shown in FIGS. 2A-2B et seq., can be used.

Each server blade 103 can include one or more IT components (e.g., CPUs, GPUs, memory, and/or storage devices). Each IT component can perform data processing tasks, where the IT component can include software installed in a storage device, loaded into the memory, and executed by one or more processors to perform the data processing tasks. Server blades 103 can include a host server (referred to as a host node) coupled to one or more compute servers (also referred to as compute nodes). The host server (having one or more CPUs) typically interfaces with clients over a network (e.g., Internet) to receive a request for a particular service such as storage services (e.g., cloud-based storage services such as backup and/or restoration), executing an application to perform certain operations (e.g., image processing, deep data learning algorithms or modeling, etc., as a part of a software-as-a-service or SaaS platform). In response to the request, the host server distributes the tasks to one or more of the compute servers (having one or more GPUs) managed by the host server. The compute servers perform the actual tasks, which can generate heat during the operations.

Electronic rack 100 further includes RMU 102 configured to provide and manage power supplied to server blades 103 and CDU 101. RMU 102 can be coupled to a power supply unit (not shown) to manage the power consumption of the power supply unit. The power supply unit can include the necessary circuitry (e.g., an alternating current (AC) to direct current (DC) or DC to DC power converter, battery, transformer, or regulator, etc.) to provide power to the rest of the components of electronic rack 100.

In one embodiment, RMU 102 includes optimal control logic 111 and rack management controller (RMC) 122. The optimal control logic 111 is coupled to at least some of server blades 103 to receive operating status of each of the server blades 103, such as processor temperatures of the processors, the current pump speed of the liquid pump 112, and liquid temperature of the cooling liquid, etc. Based on this information, optimal control logic 111 determines an optimal pump speed of the liquid pump 112 by optimizing a predetermined objective function, such that the output of the objective function reaches the maximum while a set of predetermined constraints is satisfied. Based on the optimal pump speed, RMC 122 is configured to send a signal to pump controller 110 to control the pump speed of liquid pump 112 based on the optimal pump speed.

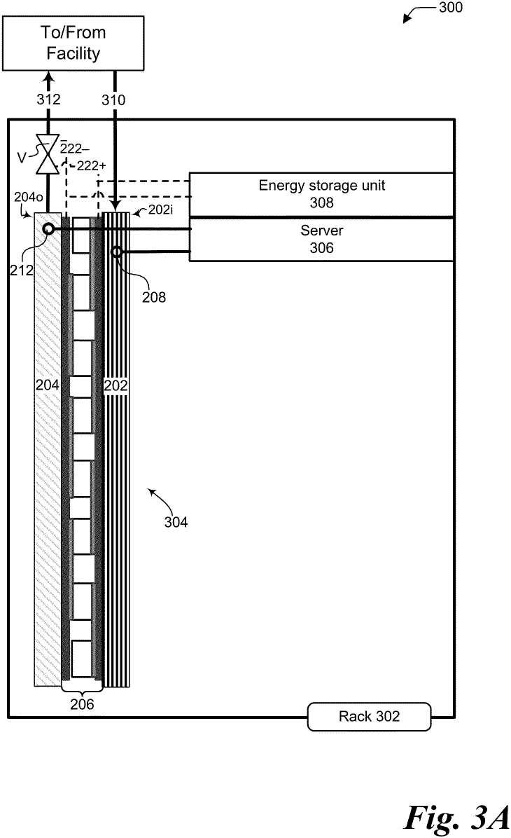

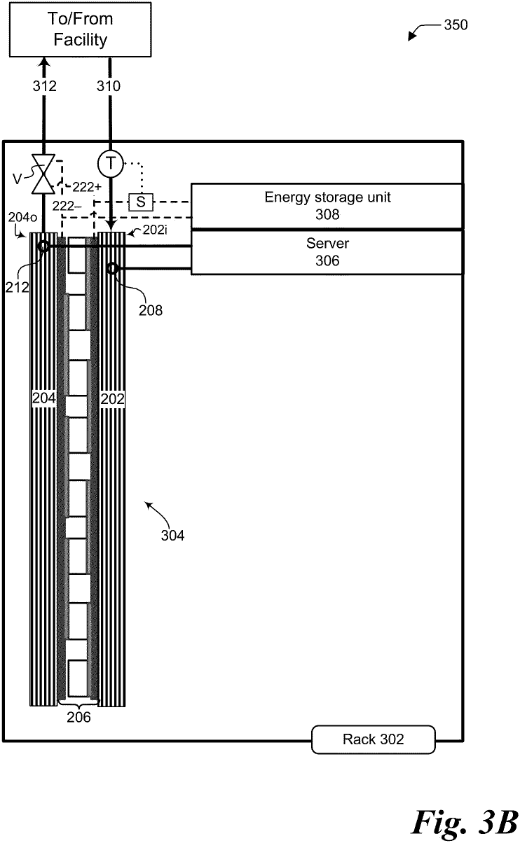

FIGS. 2A-2B together illustrate an embodiment of fluid distributor 200. FIG. 2A is a top view, FIG. 2B a cross-sectional view taken substantially along section line B-B in FIG. 2A. Embodiments of fluid distributor 200 can be used as part of a cooling loop in a fluid cooling system (see, e.g., FIG. 3A et seq.).

Fluid distributor 200 includes three main components: a supply loop or conduit 202, a return loop or conduit 204, and a thermoelectric device (TED) 206 sandwiched between the supply and return conduits. In this context, a loop or conduit is any element through which a fluid can move. Examples of conduits include pipes, tubes, ducts, manifolds, etc. The distributor can be built with a standard length and standard diameter for better fit in data center use cases. In another embodiment, the end of the distributor can be packaged with fluid moving parts powered by the TED packaged between the conduits. The entire distributor can be packaged as one part.

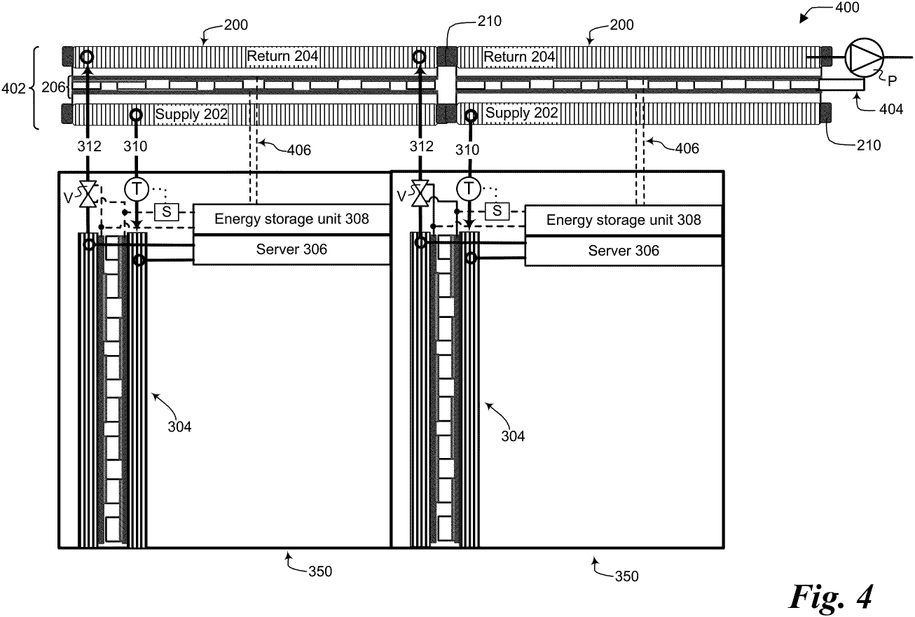

Supply conduit 202 functions as a fluid supply transport or a fluid supply distributor and includes a main inlet 202i and a main outlet 202o; return conduit 204 functions as a fluid return transport or fluid return distributor and includes a main inlet 204i and a main outlet 204o. In the illustrated embodiment main inlets 202i and 204i are on the same side of distributor 200, as are the main outlets 202o and 204o, indicating that fluid flows in the same direction through both conduits. But in other embodiments fluid can flow in opposite directions in the two conduits. In some embodiments, connectors 210 can be coupled to the main inlets and outlets of supply conduit 202 and return conduit 204 to make fluid distributor 200 modular so that it can be quickly and easily connected with other fluid distributors (see, e.g., FIG. 4). In one embodiment connectors 210 can be dripless quick-disconnect connectors, but in other embodiments they can be other types of connectors such as dripless blind-mating connectors.

Supply conduit 202 includes one or more auxiliary outlets 208 by which components such a server can be fluidly coupled to supply conduit 202, for instance in an embodiment where fluid distributor 200 is used as a manifold (see, e.g., FIGS. 3A-3B). Similarly, return conduit 204 includes one or more auxiliary outlets 212 by which components such a server can be fluidly coupled to return conduit 204, for instance in an embodiment where fluid distributor 200 is used as a manifold (see, e.g., FIGS. 3A-3B). In the illustrated embodiment supply conduit 202 has two auxiliary outlets 208 and return conduit 204 hast two auxiliary inlets 212, but in other embodiments supply conduit 202 can include more or less auxiliary outlets than shown, return conduit 204 can include more or less auxiliary inlets than shown, and the number of auxiliary outlets need not be the same as the number of auxiliary inlets. In embodiments where distributor 200 is used simply as a fluid transport (i.e., all fluid entering through main inlets exits through the main outlets) the conduits can include no auxiliary inlets or outlets.

In embodiments with multiple auxiliary outlets 208 or multiple auxiliary inlets 212, not all the auxiliary outlets and inlets need be used; for instance, if supply conduit 202 has four auxiliary outlets but only two are needed, the other two can be capped or otherwise sealed off. In one embodiment, the auxiliary outlets can be designed with dripless quick disconnects so that they are automatically sealed off if not engaged with mating connectors. In an embodiment where fluid distributor 200 is used as a manifold, the main outlet of supply conduit 202 and the main inlet of return conduit 204 can be capped, so that in supply conduit 202 fluid enters through main inlet 202i and exits through auxiliary outlets 208, and in return conduit 204 fluid enters through auxiliary inlets 212 and exits through main outlet 204o. The outlets 208 and 212 can all be assembled with dripless connectors.

Thermoelectric device (TED) 206 is sandwiched between, and in thermal contact with, a pair of thermally conductive layers 214. Thermally conductive layers 214 are in turn thermally coupled to supply conduit 202 and return conduit 204. In this context, thermally coupled means coupled in a way that heat can flow from one conduit to the other. In one embodiment conductive layers 214 can be made of material with high thermal conductivity to aid heat transfer between the return and supply conduits; the material can be a metal or a non-metal with high thermal conductivity.

Thermoelectric device (TED) 206 includes multiple semiconductor pillars 216, including alternating p-type and n-type semiconductors, electrically connected in series by conductors 218. In one embodiment semiconductors that include different trivalent impurities and pentavalent impurities can be used. The multiple semiconductor pillars 216 and conductors 218 are sandwiched between a pair of electrically-insulating layers 220. In one embodiment, insulating layers 220 can be made of materials that are thermally conductive but electrically insulating, but other materials can be used in other embodiments. In the illustrated embodiment, TED 206 is shown as a single unit, but in other embodiments TED 206 can be a TED assembly that includes multiple individual TEDs electrically connected; in embodiments with multiple individual TEDs, the individual TEDs can be can be electrically coupled in series, in parallel, or stacked onto each other, depending on the design. In an embodiment with a TED assembly made up of multiple individual TEDs, the semiconductor pillars in individual TEDs can use different types of impurities—one individual TED can use trivalent impurities, another individual TED can use pentavalent impurities, yet another individual TED can use both trivalent and pentavalent impurities, and so on — so that the TED assembly can be tailored to improve electrical generation.

A pair of electrical leads or wires 222, including a positive lead 222+ and a negative lead 222-, are electrically coupled to thermoelectric device 206. Thermoelectric device 206 can operate in two modes. In principle, if electricity is supplied to thermoelectric device 206 through leads 222 (i.e., if TED 206 consumes electricity), it operates as a thermoelectric cooler (TEC) that creates a heat flux. If no electricity is supplied to TED 206 but a heat flux is applied across the TED, it generates electricity—i.e., it operates as a thermoelectric generator that can provide electricity to other components through leads 222. Thermoelectric devices are commercially available. In addition, a customized thermoelectric device may be used for better performance in the presented liquid cooling use cases, such as the temperature situations.

To assemble fluid distributor 200, thermoelectric device 206 is sandwiched between thermally conductive layers 214. The assembly including thermoelectric device 202 and conductive layer 214 is then sandwiched between supply conduit 202 and return conduit 204, so that conductive layers 214 are in thermal contact with the supply and return conduits. In one embodiment conductive layers 214 can be positioned in direct contact with supply conduit 202 and return conduit 204, with nothing intervening between them, but in other embodiments a material such as a thermal interface material (TIM) can be put between conductive layers 214 and the supply and return conduits. In some embodiments supply conduit 202 and return conduit 204 need not be thermally coupled to conductive layers 214 in the same way. For instance, in some embodiments one conductive layer 214 can be directly coupled to one conduit while the other conductive layer 214 can be thermally coupled to the other conduit with a thermal interface material. Conducting layer 214 has two main functions: conducting the heat and enabling a good thermal contact with the TED.

During operation, the supply conduit 202 receives cool fluid and return conduit 204 receives hot fluid. The temperature difference between supply and return conduits enables the TED to generate electricity converted from the heat. In this embodiment, then, a portion of the thermal load does not end up in the cooling system, but rather is converted into electricity. Specific embodiments of the operation of fluid distributor 200 are described below in connection with FIG. 3A et seq.

FIGS. 3A-3B illustrate embodiments of rack cooling systems with a rack manifold that uses a fluid distributor such as fluid distributor 200. FIG. 3A illustrates a rack cooling system 300. Rack cooling system 300 has as its primary components a rack 302, within which is housed a rack manifold 304. Also housed within the rack are one or more servers 306 and an energy storage unit 308. Rack 302 can be a standard data center rack in one embodiment.

Rack manifold 304 is formed using an embodiment of fluid distributor 200 in which supply outlet 202o and return inlet 204i have been capped. In the illustrated embodiment, rack manifold 304 does not include quick disconnect connectors at the supply inlet 202i or return outlet 204o, but other embodiments of rack manifold 304 can include these connectors. Supply conduit 202 is fluidly coupled to a fluid supply, such as the fluid supply associated with a data center facility, by fluid connection 310. Similarly, return conduit 204 is coupled to a fluid return, such as a fluid return associated with a data center facility, by fluid connection 312.

Fluid connection 312 has a valve V coupled therein, and valve V is electrically coupled to TED 206 by leads 222+ and 222-. In the illustrated embodiment, valve V is an electrically-activated valve whose open ratio varies with the voltage or current supplied to it by TED 206. The valve’s open ratio can take on any value between 0 and 1 and is a measure of how open the valve is: in one embodiment, for instance, when the open ratio is 0 the valve is fully closed, when the open ratio is 1 the valve is fully open, when the open ratio is ½ the valve is half open, and so on.

One or more servers 306 are fluidly coupled to supply conduit 202 and return conduit 204 using each conduit’s auxiliary fluid connections—auxiliary fluid connections 208 in supply conduit 202 and auxiliary connections 212 in return conduit 204. The illustrated embodiment has only a single server 306, but other embodiments can of course include more than one server commensurate with the number of auxiliary fluid connections on supply conduit 202 and return conduit 204.

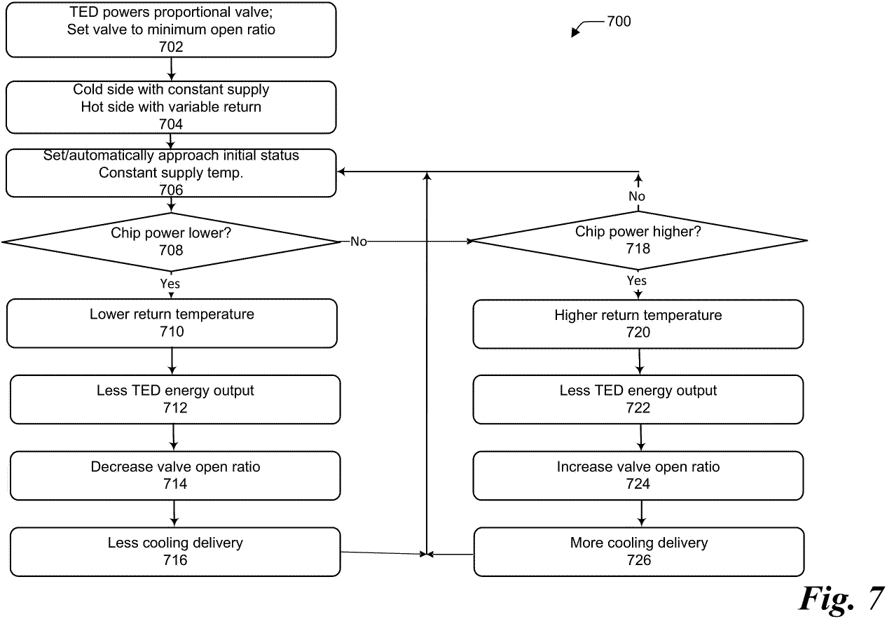

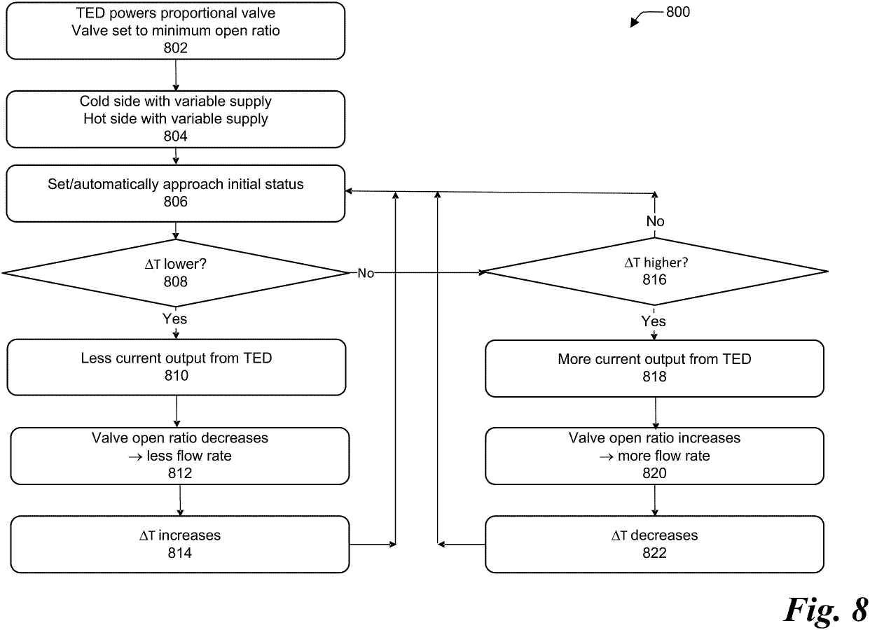

In operation of system 300, cooling fluid from a data center facility flows into supply conduit 202 through fluid connection 310. From supply conduit 202, cooling fluid flows out through auxiliary connection 208 into server 306, where it flows through the server’s liquid-cooling system. As the cooling fluid flows through the server’s liquid cooling system, it absorbs heat and its temperature increases, so that hot cooling fluid exits server 306 and is directed through auxiliary connection 212 into return conduit 204. Hot cooling fluid from return conduit 204 then flows back to the facility through fluid connection 312 and valve V. During operation, the open ratio of valve V is controlled by the voltage or current supplied to it by TED 206, which in turn depends on the temperature of the fluid in return conduit 204 and the temperature difference ΔT between the supply and return conduits. In one embodiment, for instance, the open ratio of valve V increases with increased voltage or current received from TED 206; a greater ΔT between supply and return conduits causes TED 206 to generate more electricity, which increases the open ratio of valve V and results in a higher flow rate of cooling fluid into manifold 304. A lower ΔT results in less electricity form the TED and a lower open ratio for the valve. The result is a self-regulating design that automatically adjusts to power changes in the servers, as discussed further below in connection with FIGS. 7-8.

FIG. 3B illustrates a rack cooling system 350. Rack cooling system 350 is in most respects similar to rack cooling system 300: it includes a rack 302 within which is housed a rack manifold 304. Also housed within the rack are one or more servers 306 and an energy storage unit 308. Rack 302 can be a standard data center rack in one embodiment. The primary difference between rack cooling system to 350 and 300 is that rack cooling system 350 includes a temperature control coupled to valve V.

As in system 300, in system 350 valve V is electrically coupled to TED 206 by electrical connections 222+ and 222-. System 350 also includes an energy storage unit 308, such as a battery in one embodiment, that is electrically coupled to connections 222+ and 222-. Energy storage unit 308 can store electrical energy that can then be selectively used to control valve V. A temperature sensor T is fluidly coupled into supply connection 310 and is communicatively coupled to a switch S that is coupled into one of the electrical connections between energy storage unit 308 and the electrical connections 222+ or 222-. Temperature sensor T measures the temperature of the fluid being supplied by the facility to supply conduit 202, so that the rack cooling is based on the characteristic of the cooling system of the data center as well as the performance of the TED. With the temperature control, the system can be operated more efficiently. Basically, with the same temperature difference between the hot and cold side, the lower the supply temperature, the more power can be generated. In this design, the supply fluid temperature is measured by temperature sensor T and it controls the switch for connecting and disconnecting the charging loop between the TEG and energy storage unit 308. Embodiments of the operation of system 350 are described below in connection with FIGS. 6-8. Theoretically, the supply fluid temperature is controlled only by the external cooling system such as facility loop. It does not impact by the TED or the internal power.

FIG. 4 illustrates an embodiment of a data center 400. Data center 400 includes one or more racks 350 that are coupled to a facility fluid distributor 402. The illustrated embodiment has two racks 350, but other embodiments can have more or less racks than shown. Racks 350 are as described above for FIGS. 3A-3B: each includes a rack manifold 304, one or more servers 306, an energy storage unit 308, valve V, temperature sensor T, switch S, and the electrical connections between these elements.

Facility fluid distributor 402 includes one or more fluid distributors 200. The illustrated embodiment has two fluid distributors 200 coupled to each other in series using quick-disconnect fittings 210, but other embodiments of fluid distributor 402 can include only a single fluid distributor 200 or can include more than two fluid distributors 200 by connecting additional fluid distributors in series as shown. In still other embodiments, facility fluid distributor can be formed by coupling fluid distributors 200 to conventional fluid conduits such as pipes and tubes that are not formed into an assembly like fluid distributor 200. Where there are multiple fluid distributors 200, the combined supply conduits 202 form a facility supply conduit and the combined return conduits form a facility return conduit. The illustrated embodiment includes a pump P fluidly coupled into the facility return conduit 204 and electrically coupled to the TED 206 in fluid distributor 200 by electrical connections 404, but in other embodiments pump P can be coupled in the facility supply conduit or can be omitted altogether. When present, pump P helps to accelerate (i.e., increase the flow rate of) fluid flowing through the facility return conduit.

Facility fluid distributor 402 is fluidly connected to the manifold 304 of each rack 350. To create fluid connections between facility distributor 402 and each manifold 304, the main inlet of each rack supply conduit is fluidly coupled to an auxiliary outlet in the facility supply conduit by fluid connection 310, and the main outlet of each rack return conduit is fluidly coupled to an auxiliary inlet in the facility return conduit by fluid connection 312. In addition to being electrically coupled to the TED of the rack manifold in the rack in which dislocated, each energy storage unit 308 is additionally electrically coupled to a TED in facility fluid distributor 402 by electrical connections 406.

System 400, then, uses embodiments of distributor 200 for internal rack fluid distribution and external facility fluid distribution. The internal distribution embodiments are used for distributing fluid and recirculating fluid for servers in racks and the external embodiments are used for disturbing among the racks. There are several possible variations of this embodiment. For instance, one embodiment the number of distributors 200 in the facility loop can be customized. Two are shown in the figure, and in one embodiment the rest of the facility loop (not shown in the drawing) can be made up of normal fluid transport hardware such as pipes and tubes. This is because two distributors may enable the most efficient power generation using the temperature differences between the supply and return. In other embodiments, more distributors 200 can be added to the facility loop to accommodate a greater number of racks.

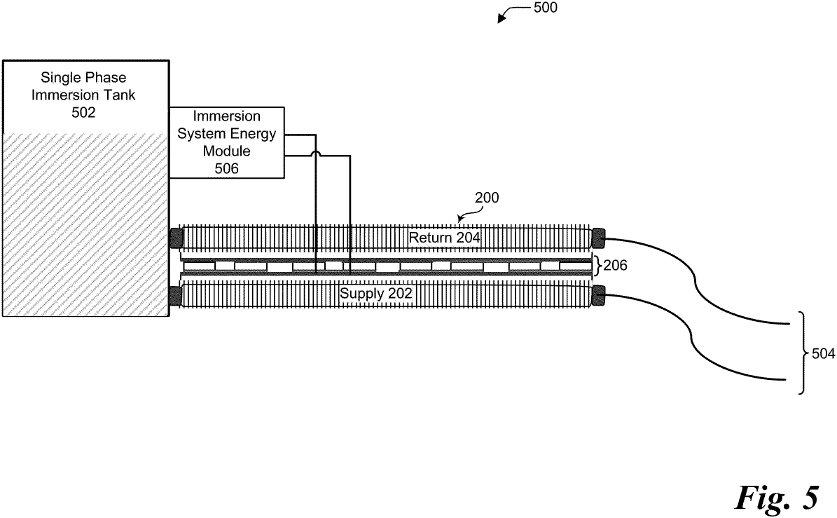

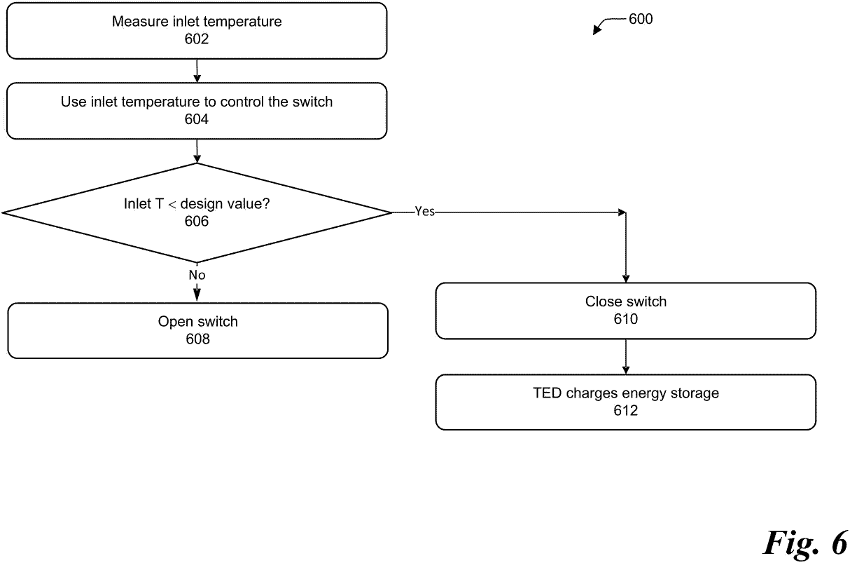

FIG. 5 illustrates an embodiment of a single phase immersion system 500. Immersion system 500 includes a single-phase immersion tank 502 that is fluidly coupled to a fluid distributor 200. Fluid distributor 200 is also connected by fluid connections 504 to other fluid elements, such as a facility supply and return in one embodiment. An immersion system energy module 506 is electrically coupled to TED 206 within fluid distributor 200. In operation, cool fluid enters single phase immersion tank 502 through supply conduit 202. Fluid in single phase immersion tank 502 is heated by heat-generating electronic components, and the heated fluid exits the single phase immersion tank through return conduit 204. As in other embodiments, the temperature difference ΔT between return 204 and supply 202 causes TED 206 to generate electricity that is then stored in immersion system energy module 506.

FIG. 6 illustrates, in flowchart form, an embodiment of a process for operating a rack cooling system, such as rack cooling system 350, that uses a temperature sensor T on the supply side to enable power flow from the TED 206 to an energy storage unit. The process begins at block 602, where the supply inlet temperature is measured by temperature sensor T. At block 604, the inlet temperature is used to control switch S. At block 606, the process checks whether the inlet temperature is less than the design value. If at block 606 the inlet temperature is greater than or equal to a design value—i.e., it is not less than design value—the process moves to block 606 where it opens switch S, cutting off the flow of current from energy storage unit 308 to valve V.

But if at block 606 the inlet temperature is less than the design value, the process moves to block 610, where it closes switch S, thus starting a flow of current from energy storage unit 308 to valve V. The block than the process then moves to block 612, were energy storage unit 308 is charged by TED 206. Note that in this embodiment TED 206 can always supply power to and control valve V, even when no current flows to valve V from energy storage unit 308 because switch S is open. FIG. 6 shows a single control flow cycle, which means that after the operations at blocks 608 and 612, the operation returns to block 604 to start one more cycle. The time span of the cycle can be customized.

FIG. 7 illustrates, in flowchart form, embodiment of a self-regulating process for operating a rack cooling system such as rack cooling system 350 in which the rack payload or chip power—i.e., the power used by heat-generating components within the server such as CPUs, memory, graphics processing units (GPUs) and so on—can be variable. Typically, the heat generated by a heat-generating component is directly related to the power consumed by the component, so that variable power consumption leads directly to variable heat generation.

The process begins at block 702, with TED 206 powering the proportional valve V and the valve V set to a minimum non-zero open ratio. The process then moves to block 704, where the cold (supply) side temperature is constant but the hot (return) side temperature is variable; the supply side temperature is constant because it usually supplied by the facility at a constant temperature, but the return side temperature is variable because of the variable chip power. At block 706 the system is set to an initial status with a constant supply temperature, or automatically approaches this initial status as a result of the system’s self-regulation.

At block 708 the process checks whether the chip power has dropped or is otherwise lower than expected. If at block 708 the chip power is lower than expected, the process moves to block 710, where the return temperature is lower because of the lower chip power, and then moves to block 712, where the TED outputs less power because of the lower return temperature and the resulting lower ΔT between supply and return. Because of the lower return temperature less cooling fluid needs to be delivered, so that at block 714, because of the lower TED energy output at block 712, the open ratio of valve V decreases, slowing the flow of return flow and consequently, at block 716, also reducing the amount of cooling fluid delivered through the supply conduit. The process then returns to block 706 to approach the initial status. This illustrates the self-regulating aspect of the system.

If at block 708 the chip power is not higher than expected, the process moves to block 718, where it checks whether the chip power has increased or is otherwise higher than expected. If at block 718 the chip power is not higher than expected, the process returns to block 706. But if at block 718 the chip power is higher than expected the process moves to block 720, where the return temperature is higher because of the higher chip power, and then moves to block 722, where the TED outputs more power because of the higher return temperature and the resulting higher ΔT between supply and return. Because of the higher return temperature more cooling fluid needs to be delivered, so that at block 724, because of the higher TED energy output at block 722, the open ratio of valve V increases, increasing the return flow and consequently, at block 726, also increasing the amount of cooling fluid delivered through the supply conduit. The process then returns to block 706 to approach the initial status. This again illustrates the system’s self-regulation.

FIG. 8 illustrates, in flowchart form, embodiment of a self-regulating process for operating a rack cooling system such as rack cooling systems 300 or 350 in which the fluid supply can be variable. The process begins at block 802, with TED 206 powering the proportional valve V and valve V set to a minimum non-zero open ratio. The process then moves to block 804, where the cold (supply) side and the hot (return) side have variable flow rates. At block 806 the system is set to an initial ΔT (the temperature difference between the supply and return conduits in manifold 304), for instance a design ΔT, or approaches that ΔT as a result of its self-regulation as described below.

At block 808 the process checks whether ΔT has dropped or is otherwise lower than expected. If at block 808 ΔT is lower than expected, the process moves to block 810, where the TED outputs less current because of the lower ΔT. Because of the lower ΔT less cooling fluid needs to be delivered, so that at block 812, because of the lower current output by the TED at block 810, the open ratio of valve V decreases, reducing the flow rate of cooling fluid through the system. At block 814, as a result of the lower flow rate of cooling fluid ΔT increases and the process returns to block 806 where, as a result of this self-regulating aspect of the system, ΔT approaches its initial or set value.

If at block 708 ΔT not lower than expected, the process moves to block 816, where it checks whether ΔT has increased or is otherwise higher than expected. If at block 816 ΔT is not higher than expected, the process returns to block 706 where ΔT automatically approaches its initial or set value. But if at block 816 ΔT is higher than expected, the process moves to block 818, where the TED outputs more current because of the higher AT. Because of the higher TED energy output at block 818, the open ratio of valve V increases, increasing the flow rate of cooling fluid through the system. At block 822, as a result of the higher flow rate of cooling fluid, ΔT decreases and the process returns to block 806 where, as a result of this self-regulating aspect of the system, ΔT approaches its initial set value.

Other embodiments are possible besides the ones described above. For instance:
The solution can be used for different rack architectures with minor modifications.
The solution can be used for different thermal loops in a cooling system.
The design can be coupled with different energy storage systems.

The above description of embodiments is not intended to be exhaustive or to limit the invention to the described forms. Specific embodiments of, and examples for, the invention are described herein for illustrative purposes, but various modifications are possible.

What is claimed is:

1. A fluid distributor comprising:
a fluid supply conduit having a main supply inlet and a main supply outlet;
a fluid return conduit having a main return inlet and a main return outlet; and
a thermoelectric assembly sandwiched between the fluid supply conduit and the fluid return conduit, the thermoelectric assembly including a thermoelectric device sandwiched between a pair of thermally conductive layers, wherein one thermally conductive layer is in thermal contact with the fluid supply conduit and the other thermally conductive layer is in thermal contact with the fluid return conduit.

2. The fluid distributor of claim 1, further comprising quick-disconnect fittings attached to the main supply inlet, the main supply outlet, the main return inlet, and the main return outlet.

3. The fluid distributor of claim 2 wherein the fluid supply conduit includes one or more auxiliary fluid outlets and the fluid return conduit includes one or more auxiliary fluid inlets.

4. The fluid distributor of claim 1, further comprising one or more electrical connections coupled to the thermoelectric device.

5. The fluid distributor of claim 1 wherein the thermoelectric device is a composite device including multiple individual thermoelectric devices electrically coupled.

6. The fluid distributor of claim 1 wherein fluid distributor is a rack manifold with the main supply inlet adapted to be coupled to a facility fluid supply and the main return outlet adapted to be fluidly coupled to a facility fluid return.

7. The fluid distributor of claim 1, further comprising an immersion cooling tank fluidly coupled to the main supply outlet and the main return inlet are fluidly coupled to an immersion cooling tank.

8. A rack assembly comprising:
a rack adapted to house one or more pieces of IT equipment, wherein at least one of the one or more pieces of IT equipment includes a liquid-cooling system; and
a rack manifold positioned within the rack, the rack manifold including:
a rack supply conduit having a main supply inlet and one or more auxiliary supply outlets,
a rack return conduit having a main return outlet, and one or more auxiliary return inlets, and a valve that is fluidly coupled to the main return outlet, and
a thermoelectric assembly sandwiched between the rack supply conduit and the rack return conduit, the thermoelectric assembly including a thermoelectric device sandwiched between a pair of thermally conductive layers, wherein one thermally conductive layer is in thermal contact with the rack supply conduit and the other thermally conductive layer is in thermal contact with the rack return conduit,
wherein the at least one piece of IT equipment that includes a liquid-cooling system is adapted to be fluidly coupled to an auxiliary supply outlet and an auxiliary supply inlet.

9. The rack assembly of claim 8 wherein the valve is electrically coupled to the thermoelectric device, is activated by applying an electrical current, and has an opening ratio that varies with the applied electrical current.

10. The rack assembly of claim 9, further comprising a temperature sensor that measures a temperature at or upstream of the main supply inlet.

11. The rack assembly of claim 10, further comprising a switch coupled in an electrical connection between the thermoelectric device and the valve, wherein the switch can be opened and closed based on an output of the temperature sensor.

12. The rack assembly of claim 8, further comprising an energy storage unit positioned in the rack, the energy storage unit being electrically coupled to the thermoelectric device and being electrically coupled to the valve.

13. A cooling system comprising:
a facility fluid distribution system including one or more distributor modules, each distributor module including:
a fluid supply conduit having a main supply inlet, a main supply outlet, and one or more auxiliary supply outlets,
a fluid return conduit having a main return inlet, a main return outlet, and one or more auxiliary return inlets, and
a thermoelectric assembly sandwiched between the fluid supply conduit and the fluid return conduit, the thermoelectric assembly including a thermoelectric device sandwiched between a pair of thermally conductive layers, wherein one thermally conductive layer is in thermal contact with the fluid supply conduit and the other thermally conductive layer is in thermal contact with the fluid return conduit; and
one or more racks fluidly coupled to the facility fluid distribution system, wherein each rack is adapted to house one or more pieces of IT equipment, wherein at least one of the one or more pieces of IT equipment includes a liquid-cooling system.

14. The cooling system of claim 13 wherein at least one rack includes a rack manifold, the rack manifold including:
a rack supply having a main supply inlet and one or more auxiliary supply outlets, the main supply inlet being fluidly coupled to one of the one or more auxiliary supply outlets of the facility fluid distribution system;
a rack return having a main return outlet, one or more auxiliary return inlets, and a valve that is fluidly coupled to the main return outlet, the main return outlet being fluidly coupled to one of one or more auxiliary return outlets of the facility fluid distribution system; and
a thermoelectric assembly sandwiched between the rack supply and the rack return, the thermoelectric assembly including a thermoelectric device sandwiched between a pair of thermally conductive layers, wherein one thermally conductive layer is in thermal contact with the fluid supply conduit and the other thermally conductive layer is in thermal contact with the fluid return conduit.

15. The cooling system of claim 14 wherein the valve is electrically coupled to the thermoelectric device, is activated by applying an electrical current, and has an opening ratio that varies with the applied electrical current.

16. The cooling system of claim 14, further comprising a temperature sensor that measures the temperature at or upstream of the main supply inlet.

17. The cooling system of claim 16, further comprising a switch coupled in an electrical connection between the thermoelectric device and the valve, wherein the switch can be opened and closed based on an output of the temperature sensor.

18. The cooling system of claim 14, further comprising an energy storage unit positioned in the rack, the energy storage unit being electrically coupled to the thermoelectric device and being electrically coupled to the valve.

19. The cooling system of claim 13 wherein when the facility fluid distribution system includes two or more distributor modules, the distributor modules are coupled in series so that:
each fluid supply conduit has its main supply inlet coupled to the main supply outlet of an upstream distributor module and its main supply outlet coupled to the main supply inlet of a downstream distributor module; and
each fluid return conduit has its main return inlet coupled to the main return outlet of an upstream distributor module and its main return outlet coupled to the main return inlet of a downstream distributor module.

20. The cooling system of claim 13, further comprising a pump fluidly coupled to the fluid return conduit and electrically coupled to a thermoelectric device of at least one distributor module in the facility fluid distribution system.
